(19) United States
(12) Patent Application Publication
(10) Pub. No.: US 2010/0108371 A1
(43) Pub. Date: May 6, 2010

(54) WIRING BOARD WITH BUILT-IN ELECTRONIC COMPONENT AND METHOD FOR MANUFACTURING THE SAME

(75) Inventors: Toshiki FURUTANI, Ogaki-shi (JP); Takeshi FURUSAWA, Ogaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: IBIDEN CO., LTD., Ogaki-shi (JP)

(21) Appl. No.: 12/488,177

(22) Filed: Jun. 19, 2009

Related U.S. Application Data
(60) Provisional application No. 61/112,035, filed on Nov. 6, 2008.

(51) Int. Cl. H05K 1/16; H05K 1/11; H05K 3/30

(52) U.S. Cl. 174/260; 174/263; 29/834; 29/840; 29/841; 29/874

(57) ABSTRACT

A wiring board with a built-in electronic component in which an electronic component is flip-chip mounted to be built in, including a conductive-pattern layer, a connection terminal formed in the conductive-pattern layer and electrically connected to the electronic component, and a solder resist layer formed on the conductive-pattern layer. The solder resist layer is formed around the connection terminal on the conductive-pattern layer, but it is not formed in at least part of the other region on the conductive-pattern layer.

### CROSS-REFERENCE TO RELATED APPLICATIONS

The present application claims the benefits of priority to U.S. Application No. 61/112,035, filed Nov. 6, 2008. The contents of that application are incorporated herein by reference in their entirety.

### BACKGROUND OF THE INVENTION

1. Field of the Invention

The present invention is related to a wiring board with a built-in electronic component, which accommodates electronic components such as a semiconductor element.

2. Discussion of the Background

Recently, various technologies are suggested that electronic components, such as an IC chip, be accommodated in (built-in) wiring boards (for example, Japanese Laid-Open Patent Publication 2004-7006).

As disclosed in Japanese Laid-Open Patent Publication 2004-7006, by building electronic components into wiring boards, multilayer wiring boards may become highly functional and highly integrated. Namely, by accommodating electronic components inside, other electronic components may be mounted on the surface-layer mounting regions. The contents of this publication are incorporated herein by reference in their entirety.

### SUMMARY OF THE INVENTION

A wiring board with a built-in electronic component according to one aspect of the present invention has a conductive-pattern layer, a connection terminal formed in the conductive-pattern layer and electrically connected to an electronic component which is flip-chip mounted, and a solder resist layer formed on the conductive-pattern layer. In the wiring board, the solder resist layer is formed around the connection terminal on the conductive-pattern layer, but it is not formed in at least part of the other regions on the conductive-pattern layer.

Also, a method for manufacturing a wiring board with a built-in electronic component according to another aspect of the present invention includes the following: forming a conductive-pattern layer on a metal foil of a laminated base material where the metal foil is arranged on a support body; forming a solder resist layer having a predetermined opening portion in part of the region on the conductive-pattern layer; forming a connection terminal by forming a connection layer at the spot on the conductive-pattern layer which corresponds to the opening portion of the solder resist layer; arranging the electronic component on the laminated base material in such a way that the circuit-formed surface of the electronic component faces the surface where the connection terminal is formed, and to electrically connect the electronic component and the connection terminal; coating with an insulative material the electronic component after it is mounted; removing the support body; and removing the exposed metal foil.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a cross-sectional view showing the structure of a support base material;

FIG. 1B is a cross-sectional view showing a phase in which the first underlayer and the second underlayer are formed on the support base material;

FIG. 1C is a cross-sectional view showing a phase in which a photosensitive resist is laminated on the substrate shown in FIG. 1B;

FIG. 1D is a cross-sectional view showing a phase in which a plating resist layer is formed on the substrate shown in FIG. 1B;

FIG. 1E is a cross-sectional view showing a phase in which a copper-plated layer is formed on the substrate shown in FIG. 1D;

FIG. 1F is a cross-sectional view showing a phase in which the plating resist layer is removed from the substrate shown in FIG. 1E;

FIG. 1G is a cross-sectional view showing a phase in which a solder resist layer is formed on the substrate shown in FIG. 1F;

FIG. 1H is a cross-sectional view showing a phase in which a connection layer is formed on the substrate shown in FIG. 1G;

FIG. 2A is a cross-sectional view showing a step to mount an electronic component;

FIG. 2B is a cross-sectional view showing a phase after an underfill material is filled;

FIG. 3A is a cross-sectional view showing a lamination step (step 1);

FIG. 3B is a cross-sectional view showing a lamination step (step 2);

FIG. 3C is a cross-sectional view showing a lamination step (step 3);

FIG. 4A is a cross-sectional view showing a phase in which the carrier is removed from the substrate shown in FIG. 3C);

FIG. 4B is a cross-sectional view showing a phase in which a through-hole is formed in the substrate shown in FIG. 4A;

FIG. 4C is a cross-sectional view showing a phase after electroless copper plating is performed on the substrate shown in FIG. 4B;

FIG. 4D is a cross-sectional view showing a phase in which a plating resist layer is formed on the substrate shown in FIG. 4C;

FIG. 4E is a cross-sectional view showing a phase in which copper-plated film and through-hole conductor are formed on the substrate shown in FIG. 4D;

FIG. 4F is a cross-sectional view showing the structure of a wiring board with a built-in electronic component according to an embodiment of the present invention;

FIGS. 5A to 5E are cross-sectional views showing the steps of manufacturing a multilayer wiring board using the wiring board with a built-in electronic component shown in FIG. 4F;

FIG. 5F is a cross-sectional view showing the structure of the multilayer wiring board using the wiring board with a built-in electronic component shown in FIG. 4F;

FIG. 6 is a plan view to illustrate the formation of a solder resist layer in the present embodiment;

FIG. 7 is a plan view to illustrate the formation of a solder resist layer in another embodiment;

FIG. 8 is a plan view to illustrate the formation of a solder resist layer in yet another embodiment; and

FIG. 9 is a plan view to illustrate the formation of a solder resist layer in yet another embodiment.

### DETAILED DESCRIPTION OF THE EMBODIMENTS

The embodiments will now be described with reference to the accompanying drawings, wherein like reference numerals designate corresponding or identical elements throughout the various drawings.

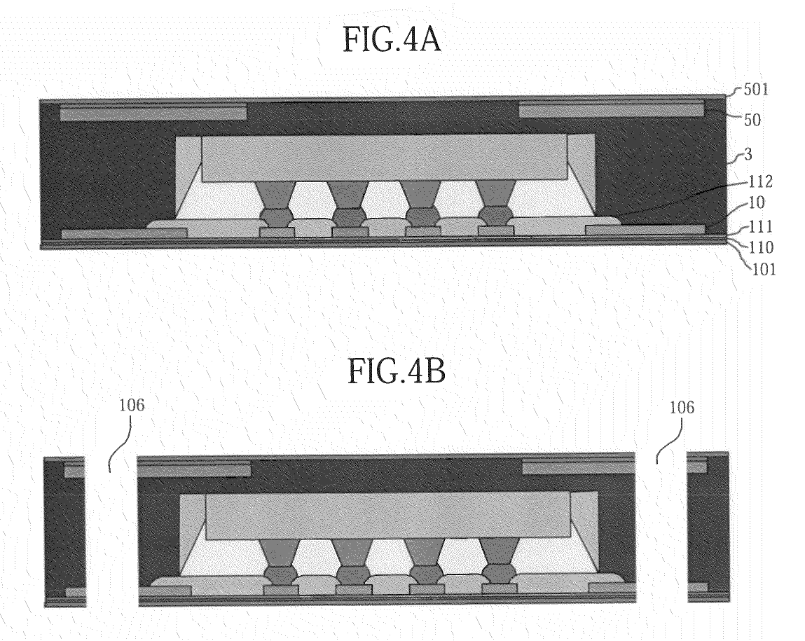

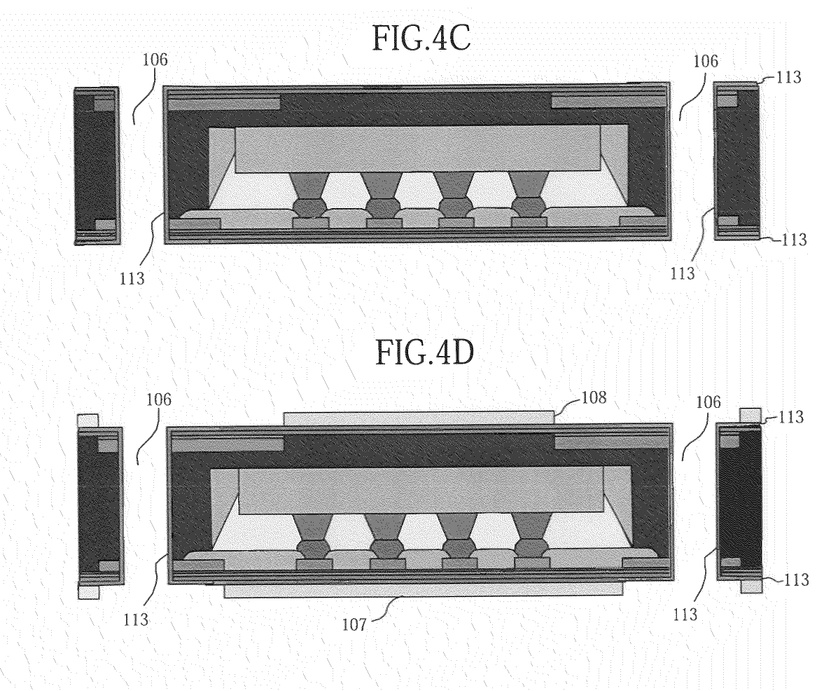

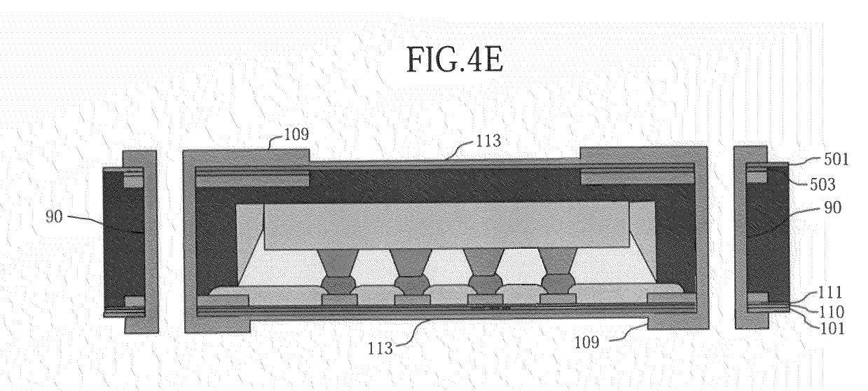

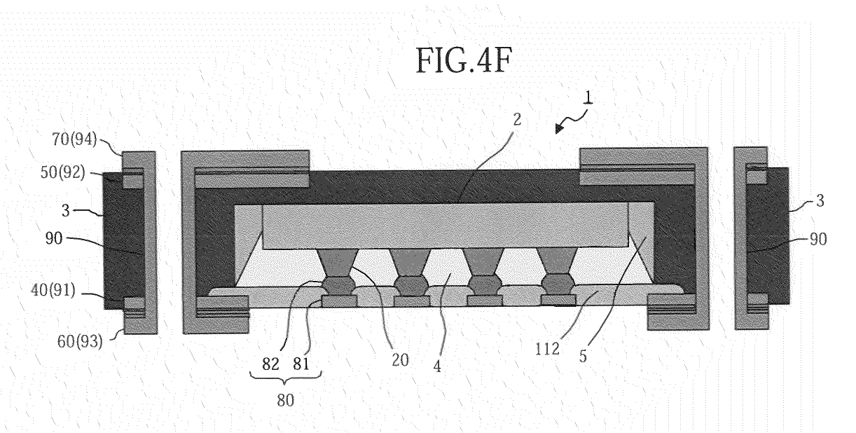

FIG. 4F is a cross-sectional view schematically showing wiring board (1) with a built-in electronic component according to the present embodiment. Wiring board (1) with a built-in electronic component is used, for example, as a core substrate or the like for a multilayer printed wiring board.

Wiring board (1) with a built-in electronic component is formed with electronic component (2), insulative material (3), underfill material (4), filler resin (5), inner-layer conductive patterns (40, 50), solder resist layer (112), outer-layer conductive patterns (60, 70), connection terminal (80) and through-hole conductor (90).

Electronic component (2) is flip-chip mounted and has multiple bumps (20) arranged in an area-array format. Bumps (20) are, for example, gold-stud bumps with an approximate thickness of 30 μm.

Insulative material (3) is a slab material formed by impregnating reinforcement material such as glass fiber, aramid fiber or the like with resin such as epoxy resin, polyester resin, polyimide resin, bismaleimide-triazine resin (BT resin), phenol resin and so forth. The present embodiment uses a prepreg. Underfill material (4) is, for example, an insulative resin containing inorganic filler such as silica or alumina. It is used to ensure the securing strength of electronic component (2), while absorbing warping generated by the differences in thermal expansion coefficients between electronic component (2) and insulative materials (such as insulative material (3) and filler resin (5)). Underfill material (4) is preferred to be formed with a thermosetting resin and inorganic filler in the amount of 40-90 weight percent. Also, the size of the filler (average particle diameter) is preferred to be in the range of 0.1 to 3.0 μm. Filler resin (5) is preferred to be formed with a thermosetting resin and inorganic filler. As for the inorganic filler, for example, Al₂O₃, MgO, BN, AlN or SiO₂ may be used. As for the thermosetting resin, highly heat-resistant resins, such as epoxy resin, phenol resin or cyanate resin, are preferred. Among those, epoxy resin is especially preferred because it has excellent heat resistance. Solder resist layer (112) is formed by screen printing, spray coating, roll coating or the like using materials such as photosensitive resins of acrylic-epoxy resins, thermosetting resins mainly containing epoxy resins, ultraviolet-setting resins and so forth. Alternatively, a photosensitive dry film of acrylic-epoxy resin may be vacuum laminated to form the solder resist layer.

Conductive pattern (40) made of copper or the like is formed inside (hereinafter referred to as the first inner layer) the first-surface side (the side opposite the surface where a circuit of electronic component (2) is formed) of wiring board (1) with a built-in electronic component. The thickness of conductive pattern (40) is approximately 15 μm. Part of conductive pattern (40) is used as pad (81) that forms connection terminal (80) or as first inner-layer through-hole land (91), which is connected to through-hole conductor (90).

Conductive pattern (50) made of copper or the like is formed inside (herein after referred to as the second inner layer) the second surface (the main surface opposite the first surface) of wiring board (1) with a built-in electronic component. Part of conductive pattern (50) becomes second inner-layer through-hole land (92), which is connected to through-hole conductor (90). The thickness of conductive pattern (50) is approximately 15 μm. First inner-layer through-hole land (91) and second inner-layer through-hole land (92) are electrically connected by means of through-hole conductor (90).

Conductive pattern (60) made of copper or the like is formed on the first surface (hereinafter referred to as the first outer layer) of wiring board (1) with a built-in electronic component. Part of conductive pattern (60) becomes first outer-layer through-hole land (93), which is connected to through-hole conductor (90). The thickness of conductive pattern (60) is approximately 20 μm.

Conductive pattern (70) made of copper or the like is formed on the second surface (herein after referred to as the second outer layer) of wiring board (1) with a built-in electronic component. Part of conductive pattern (70) becomes second outer-layer through-hole land (94), which is connected to through-hole conductor (90). The thickness of conductive pattern (70) is approximately 20 μm.

Connection terminal (80) is a terminal for electrical connection to bump (20) of electronic component (2), and is formed with pad (81) and connection layer (82). The thickness of pad (81) is approximately 15 μm and the thickness of connection layer (82) is approximately 15 μm. Connection layer (82) is formed on pad (81) (namely on conductive pattern (40)) using a metal other than that of pad (81). For example, connection layer (82) may be formed by electrolytic plating using a metal such as solder, tin, nickel, gold or their alloys. The connection layer may also be formed by printing solder paste and conducting a reflow process. Alternatively, connection layer (82) may be formed with multiple layers using a combination of such methods. However, the outermost surface layer of connection layer (82) is preferred to be made of solder.

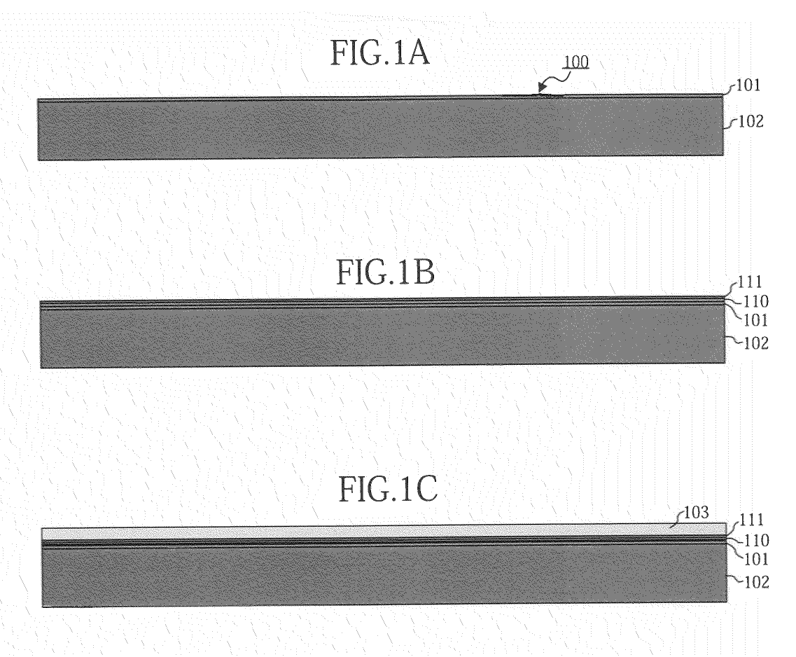

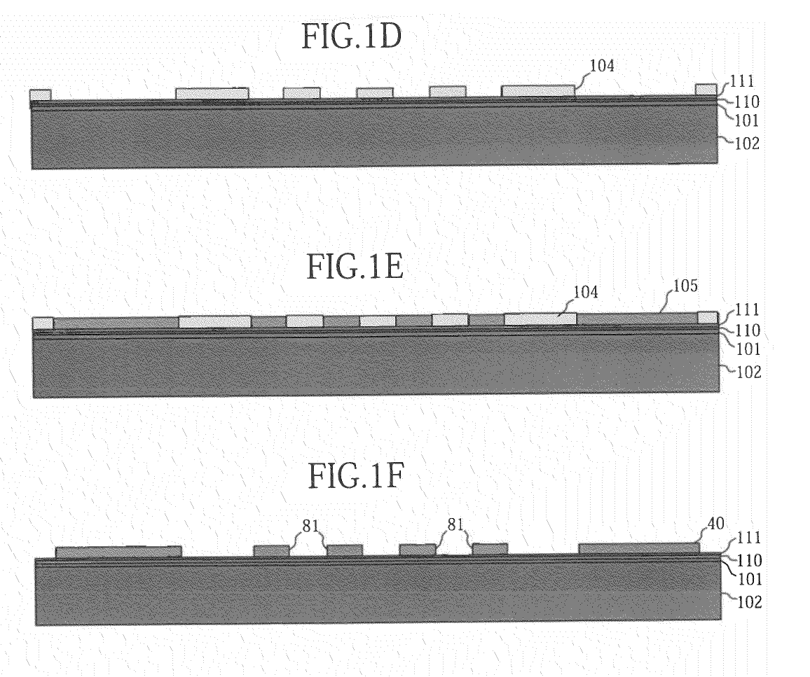

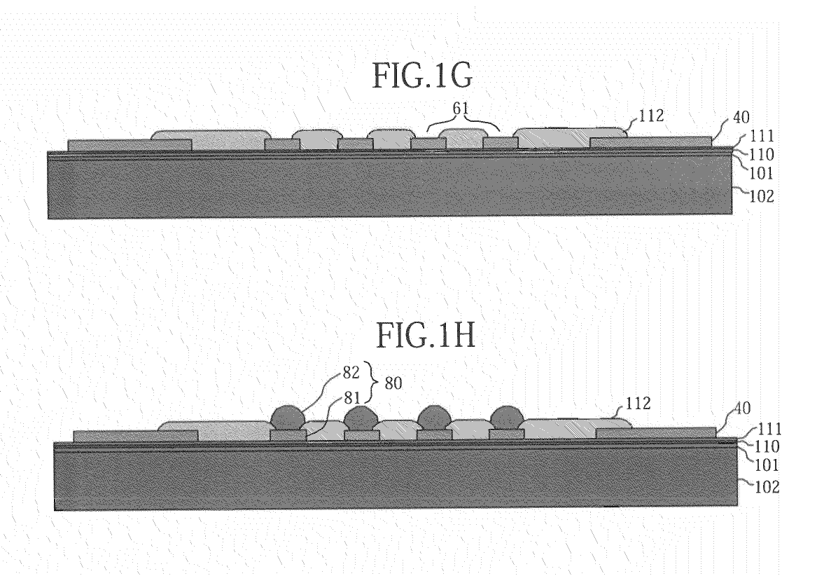

Wiring board (1) with a built-in electronic component structured as described above is characterized by solder resist layer (112), which is formed not on the entire surface of the conductive pattern but on part of its surface. In the following, a method for manufacturing wiring board (1) with a built-in electronic component is described with reference to FIGS. 1A to 4E.

(1) Steps to Form Connection Terminals (80) (FIGS. 1A-1H)

Support base material (100) is prepared as shown in FIG. 1A. Support base material (100) is copper foil with a so-called carrier; copper foil (101) and carrier (102) made of copper are adhered using an adhesive agent (removable layer) in such a way that they can be removed (separated). Here, the thickness of copper foil (101) is approximately 5 μm and the thickness of carrier (102) is approximately 70 μm. As for carrier (102), it is not limited to copper, but insulative materials may be used.

On copper foil (101) of support base material (100), connection terminals (80) to mount electronic component (2) are formed by an additive method. Before forming connection terminals (80) by an additive method, as shown in FIG. 1B, first underlayer (110) is formed using metals such as nickel to be approximately 1 μm thick on the entire surface of copper foil (101) of support base material (100) by performing electroless plating, electrolytic plating, sputtering or the like. In doing so, erosion by etching may be prevented and fine patterns may be formed.

Also, if solder resist layer (112) is formed as in the present embodiment, as shown in FIG. 1B, second underlayer (111) is formed using metals such as titanium to be approximately 0.1 μm thick on the entire surface of the first underlayer by performing electroless plating, sputtering or the like. This achieves the effect of enhancing its adhesiveness with solder resist layer (112). Here, the additive method indicates a method in which plating grows in the portions where plating resist is not formed, and then the plating resist is removed to form a conductive pattern. In the following, how to form connection terminals (80) using the additive method is described specifically.

Photosensitive resist (103) in a dry-film state is laminated on second underlayer (111) of the substrate shown in FIG. 1B (see FIG. 1C). Then, a mask film is adhered on the laminated photosensitive resist (103), which is then exposed to ultraviolet rays and developed in an alkaline solution. As a result, plating resist layer (104) is formed where only the portions corresponding to conductive pattern (40) are open (see FIG. 1D).

The substrate shown in FIG. 1D is washed with water and dried. Then, electrolytic copper plating is performed to form copper-plated layer (105) with an approximate thickness of 15 μm (see FIG. 1E). By removing plating resist layer (104), a substrate is obtained in which conductive pattern (40) and pads (81) are formed (see FIG. 1F). On the surface of the substrate shown in FIG. 1F, a photosensitive resist (solder resist) in a liquid or a dry-film state is either applied or laminated to form a solder resist layer with an approximate thickness of 20 μm. Then, a mask film with a predetermined pattern is adhered on the surface of the solder resist layer, which is exposed to ultraviolet rays and developed in an alkaline solution.

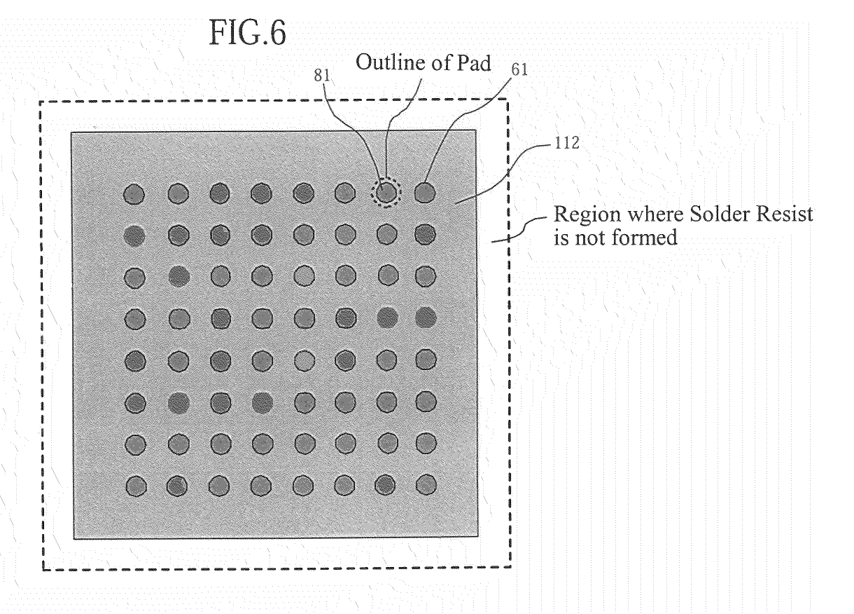

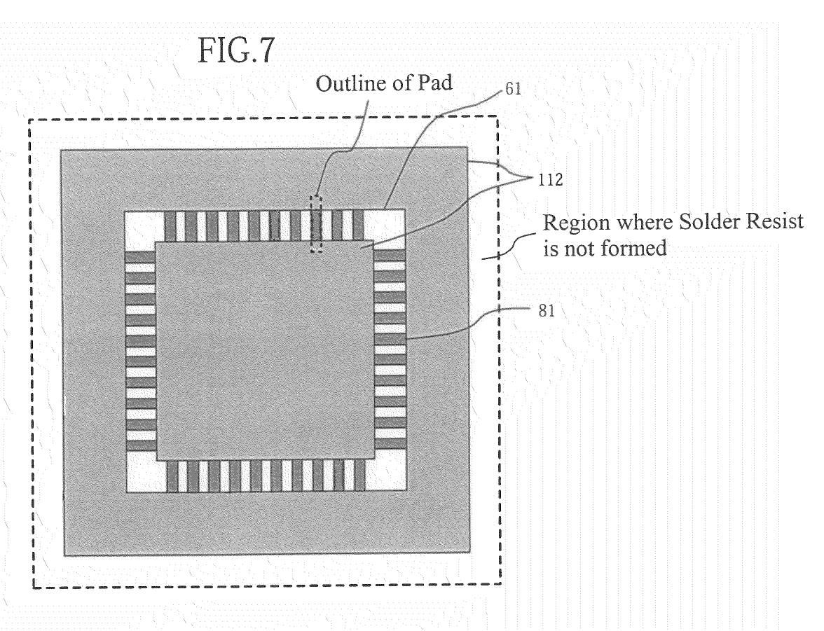

As a result, on the surface of the substrate shown in FIG. 1F, solder resist layer (112) is formed (see FIG. 1G). FIG. 6 is a plan view showing part of the substrate of FIG. 1G. As shown in FIG. 6, solder resist layer (112) is formed in the region of the surface of the substrate shown in FIG. 1G that corresponds to the circuit-formed surface of electronic component (2). In solder resist layer (112), multiple opening portions (61) are formed to expose the surfaces of their respective pads (81). More precisely, the surface of each pad (81) is not exposed entirely through opening portion (61), but at least part of the surface of each pad (81) is covered by solder resist layer (112).

Connection layer (82) is formed on pads (81) (see FIG. 1H). In the present embodiment, connection layer (82) is formed by printing solder paste and conducting a reflow. During such time, as described above, since solder resist layer (112) is formed around pads (81), solder is prevented from flowing into the portions other than pads (81). Accordingly, connection layer (82) may be easily formed on pads (81) uniformly and thickly. As described, connection terminals (80) are obtained which are to be connected to bumps (20) of electronic component (2).

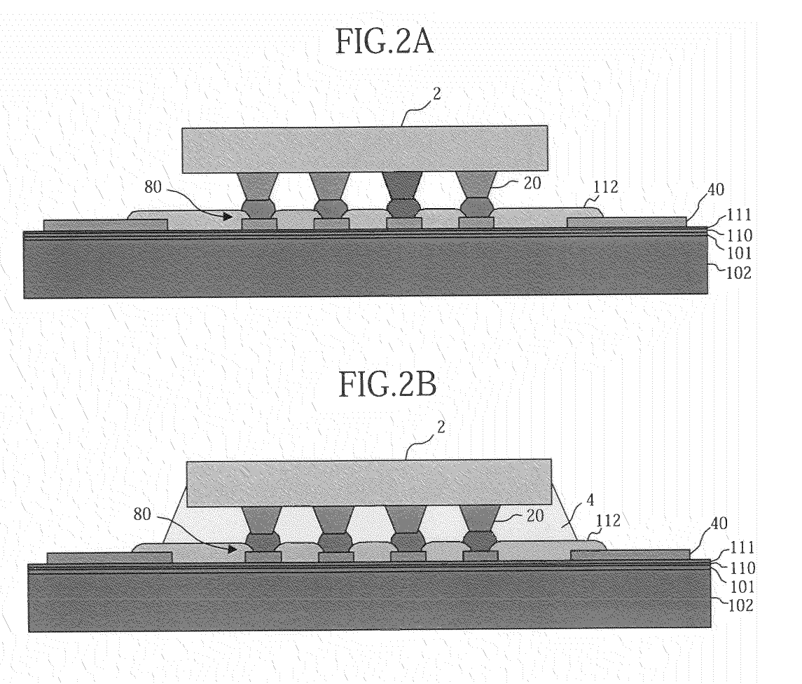

(2) Steps to Mount Electronic Component (2) (FIGS. 2A, 2B)

On the substrate shown in FIG. 1H, electronic component (2) is mounted face-down by joining bumps (20) of electronic component (2) with connection terminals (80) (see FIGS. 2A). As described above, because connection layer (82) is formed uniformly and thickly, connection reliability between bumps (20) of electronic component (2) and connection terminals (80) is ensured. After electronic component (2) is mounted, underfill material (4) is filled in the gaps between electronic component (2) and the substrate (see FIG. 2B). Underfill material (4) is, for example, insulative resin containing inorganic filler such as silica or alumina as described above.

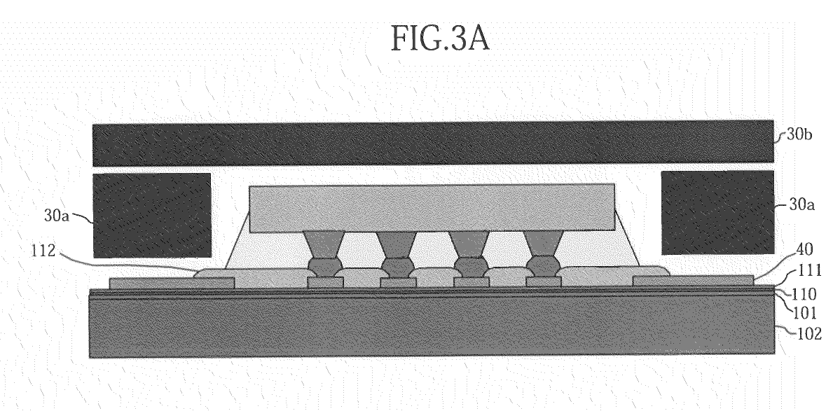

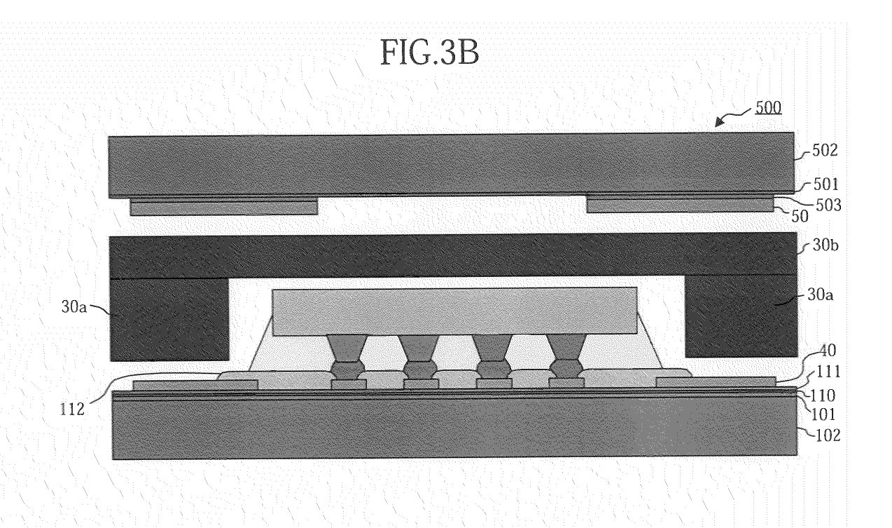

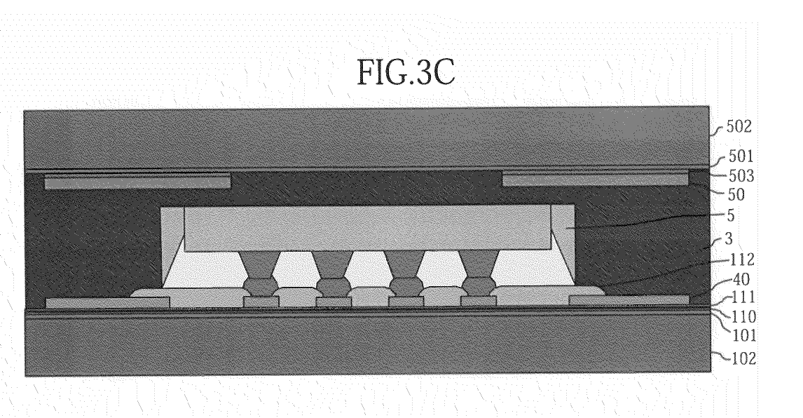

(3) Lamination Steps (FIGS. 3A-3C)

Insulative materials (30a, 30b) are arranged on the surface of the substrate shown in FIG. 2B where electronic component (2) is mounted (see FIG. 3A). Insulative materials (30a, 30b) are slab-type materials made by impregnating a reinforcing material such as glass fabric with resin (prepreg in the present embodiment). Insulative material (30a), in which a section is cut out so as to have it correspond to the configuration of electronic component (2), is arranged to surround electronic component (2) in a direction parallel to the mounting surface. To cut out such a section, punching is preferred, but mechanical drilling or laser processing may also be employed. On the other hand, insulative material (30b) does not have a hollow section, but is formed to be a sheet. It is arranged on insulative material (30a) and on the surface of electronic component (2), which is opposite the surface where bumps (20) are formed.

After insulative materials (30a, 30b) are arranged, substrate (500) having conductive pattern (50) is laminated on insulative material (30b) in such a way that the surface where conductive pattern (50) is formed faces the insulative material (30b) (see FIGS. 3B, 3C). As for the method for such a lamination, for example, autoclave lamination or hydraulic pressure lamination may be used.

A method for manufacturing substrate (500) is briefly described. A support base material having the same structure as support base material (100) is prepared (formed with copper foil (501) with an approximate thickness of 5 μm and carrier (502) with an approximate thickness of 70 μm). A photosensitive resist in a dry-film state is laminated on the support base material. A mask film with a predetermined pattern is adhered to the laminated photosensitive resist, which is then exposed and developed. Accordingly, a plating resist layer is obtained which has openings only in the areas corresponding to conductive pattern (50). The substrate with the plating resist layer is washed with water and dried, and electrolytic nickel plating is performed to obtain underlayer (503) with an approximate thickness of 1 μm. Electrolytic copper plating is further performed and a copper-plated layer with an approximate thickness of 15 μm is formed on underlayer (503). The plating resist layer is removed, and the substrate is washed with water and dried. Accordingly, substrate (500) with conductive pattern (50) is obtained.

During the above lamination, insulative material (30a) and insulative material (30b) are fused by pressure, resulting in insulative material (3) as shown in FIG. 3C. Also, during that time, the resin ingredient flows out from insulative materials (30a, 30b) and the gaps generated between electronic component (2) and insulative materials (30a, 30b) are filled with filler resin (5).

(4) Later Steps (FIGS. 4A-4E)

Carrier (102) and carrier (502) are removed (separated) from the substrate shown in FIG. 3C, and the substrate is obtained as shown in FIG. 4A. Then, by a conventional drilling method using a mechanical drill or the like, through-holes (106) are formed in the substrate shown in FIG. 4A (see FIG. 4B). After through-holes (106) are formed, electroless copper plating is performed on the substrate in FIG. 4B to form copper-plated layer (113) on both main surfaces and the inner walls of through-holes (106) (see FIG. 4C. A photosensitive resist in a dry-film state is laminated on both main surfaces of the substrate shown in FIG. 4C, and a mask film is adhered to the photosensitive resist, which is then exposed and developed. Accordingly formed are plating resist layer (107) having openings only in the portions corresponding to conductive pattern (60), and plating resist layer (108) having openings only in the portions corresponding to conductive pattern (70) (see FIG. 4D).

After the substrate shown in FIG. 4D is washed with water and dried, electrolytic copper plating is performed, and plating resist layers (107, 108) are removed. Accordingly, as shown in FIG. 4E, copper-plated film (109) and through-hole conductors (90) are formed. Unnecessary portions of copper-plated layers (113), copper foil (101) and copper foil (501) on both main surfaces of the substrate in FIG. 4E are removed using an etching solution that selectively etches copper. First underlayer (110) and second underlayer (111) are removed using an etching solution that selectively etches metals other than copper, such as nickel or titanium. In doing so, substrate (1) with a built-in electronic component is obtained in which conductive pattern (60) (first outer-layer through-hole lands (93)) and conductive pattern (70) (second outer-layer through-hole lands (94)) are formed as shown in FIG. 4F. When first underlayer (110) and second underlayer (111) are etched away, since an etching solution that selectively etches metals other than copper is used, conductive pattern (40) is protected without being exposed to the effects of the etching. Moreover, since pads (81) are embedded in solder resist layer (112) and do not protrude from its surface, the pattern seldom becomes thinner during the etching, and thus the fine pattern may be maintained.

Substrate (1) with a built-in electronic component manufactured as described above has excellent features as follows.

(1) Since electronic component (2) is accommodated (built in), other electronic components or the like may be mounted on the surface mounting region. Thus, the substrate may become highly functional. Also, since an electronic component to be built in is flip-chip mounted, thinner type (more compact) substrates may be achieved.

(2) Conductive pattern (40) and connection terminals (80) may be formed with a fine pitch (for example, 50 μm) through the following procedures: (a) connection terminals (80) for mounting an electronic component are formed beforehand on support base material (100); (b) support base material (100) is made thick (approximately 75 μm); and (c) conductive pattern (40) and connection terminals (80) are formed by an additive method. In addition, since carrier (102) of support base material (100) may be easily removed by peeling, when unnecessary metal layers are removed, potential damage to connection terminals (80) may be minimized. Furthermore, since connection terminals (80) and conductive pattern (40) are not etched or the like in the later steps, the original pattern configurations may be maintained. Thus, pattern accuracy may be enhanced.

(3) Also, since accommodated electronic component (2) is covered and sealed by underfill material (4) and insulative material (3), it is secured strongly. Therefore, while laminating multiple layers in a process such as a build-up process using substrate (1) with a built-in electronic component as the core substrate, handling is easy. In addition, even during etching or the like, such impact on electronic component (2) may be minimized.

(4) Also, substrate (1) with a built-in electronic component has a structure (symmetrical structure) in which insulative materials (underfill material (4) and insulative material (3)) sandwich electronic component (2) from the bottom and top of its mounting surface. Such a symmetrical structure may ease the force from stresses (heat, vibration impact, impact from being dropped and so forth), thus resistance to warping may be ensured. Furthermore, since conductive patterns (60, 70) are respectively formed on the first surface and second surface of wiring board (1) with a built-in electronic component, resistance to warping may be strengthened even further.

(5) Also, in the layer where conductive pattern (40) is formed, since the surroundings of connection terminals (80) are coated with solder resist layer (112), solder will not adhere to unneeded portions. Thus, connection terminals (80) are protected, while insulation between conductors is secured. Moreover, in the layer where conductive pattern (40) is formed, solder resist layer (112) is not formed on its entire surface, but there are areas where the solder resist layer is not formed. Namely, solder resist with a high thermal expansion coefficient is formed only in the region where it is absolutely necessary to form such solder resist. Accordingly, warping of the substrate may be reduced.

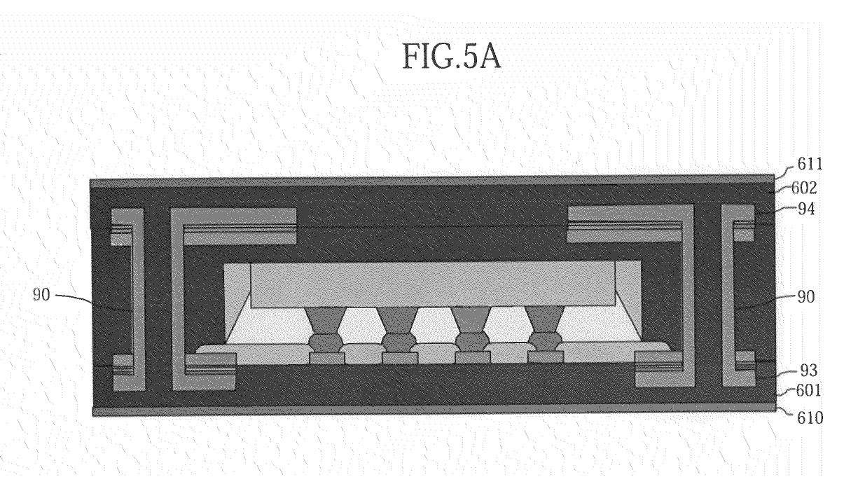

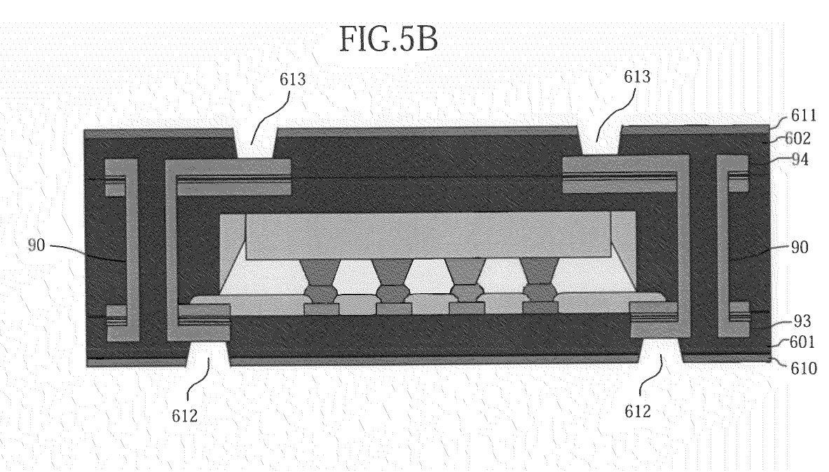

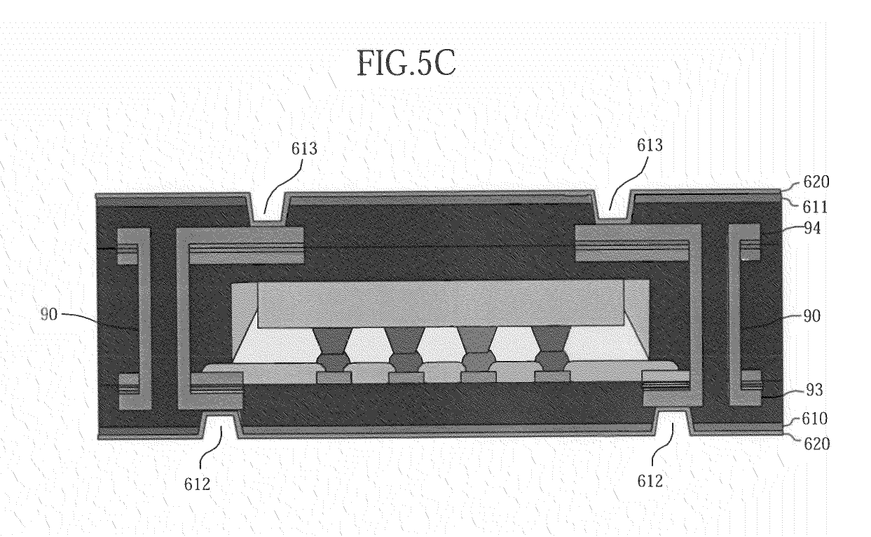

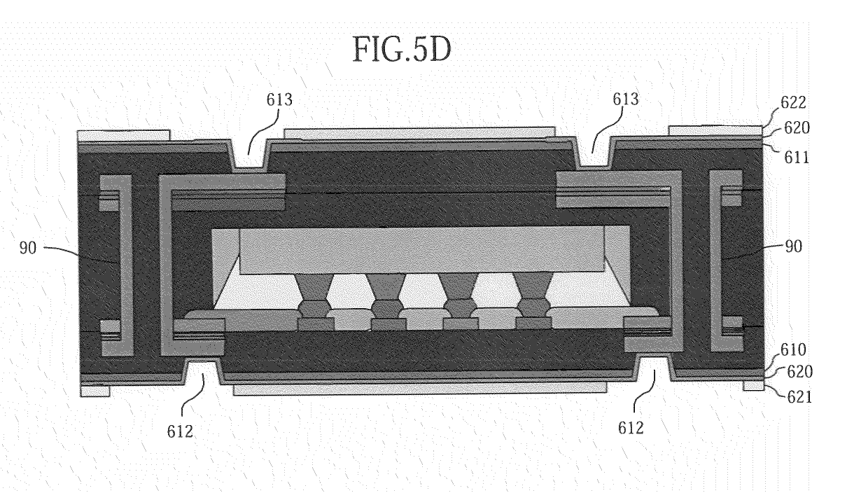

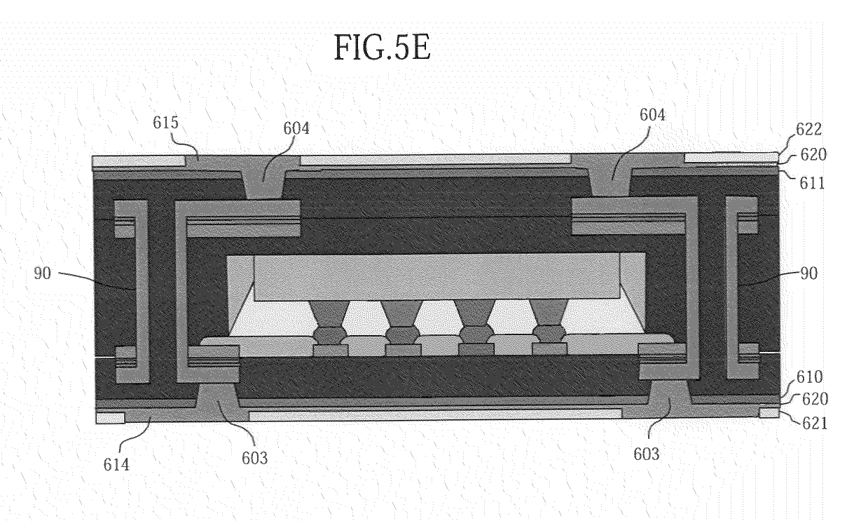

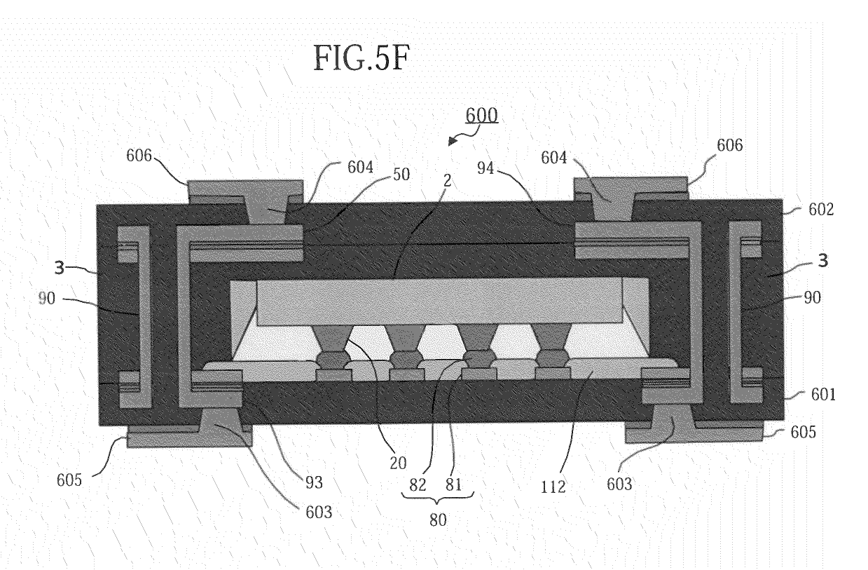

FIG. 5F is a view schematically showing multilayer wiring board (600) in which substrate (1) with a built-in electronic component shown in FIG. 4F is used as the core substrate. A method for manufacturing multilayer wiring board (600) is briefly described with reference to FIGS. 5A-5E.

On both main surfaces (on the first and second surfaces) of substrate (1) with a built-in electronic component shown in FIG. 4F, sheet-type slab materials (prepreg in the present embodiment), which are made by impregnating a reinforcing material such as glass fabric with resin, are arranged. Rolled copper foil or electrolytic copper foil is further arranged on the slab materials, which are then thermal pressed. As a result, insulation layers (601, 602) with an approximate thickness of 40 μm and copper foils (610, 611) with an approximate thickness of 12 μm are formed (see FIG. 5A). During that time, the amount of resin squeezed out from first outer-layer through-hole lands (93) and second outer-layer through-hole lands (94), and the amount of resin entering the interiors (hollow portions) of through-hole conductors (90) are offset. Accordingly, the surfaces of insulation layers (601, 602) are made flat.

Using carbon-dioxide gas (CO2) laser or UV-YAG laser or the like, laser vias (blind holes) (612, 613) are formed in the predetermined spots of both main surfaces of the substrate shown in FIG. 5A (see FIG. 5B). Electroless copper plating is performed on the entire surfaces of the substrate shown in FIG. 5B to form copper-plated layer (620) on both main surfaces and the inner surfaces of laser vias (612, 613) (see FIG. 5C). After plating resist layers (621, 622) are formed (see FIG. 5D), electrolytic copper plating is performed to form vias (603, 604) and copper-plated layers (614, 615) (see FIG. 5E). From the substrate shown in FIG. 5E, plating resist layers (621, 622) are removed, and unnecessary portions of copper foils (610, 611) and copper-plated layer (620) are etched away from both main surfaces. Accordingly, multilayer wiring board (600) is obtained in which conductive patterns (605, 606) are formed (see FIG. 5F).

The present invention is not limited to the above embodiment, but may be modified in various ways within the scope of the present invention.

For example, the formation of solder resist layer (112) is not limited to what is shown in FIG. 6. If bumps (20) of electronic component (2) are arrayed, for example, in a peripheral format, opening portions (61) of solder resist layer (112) may be configured to be rectangular frames.

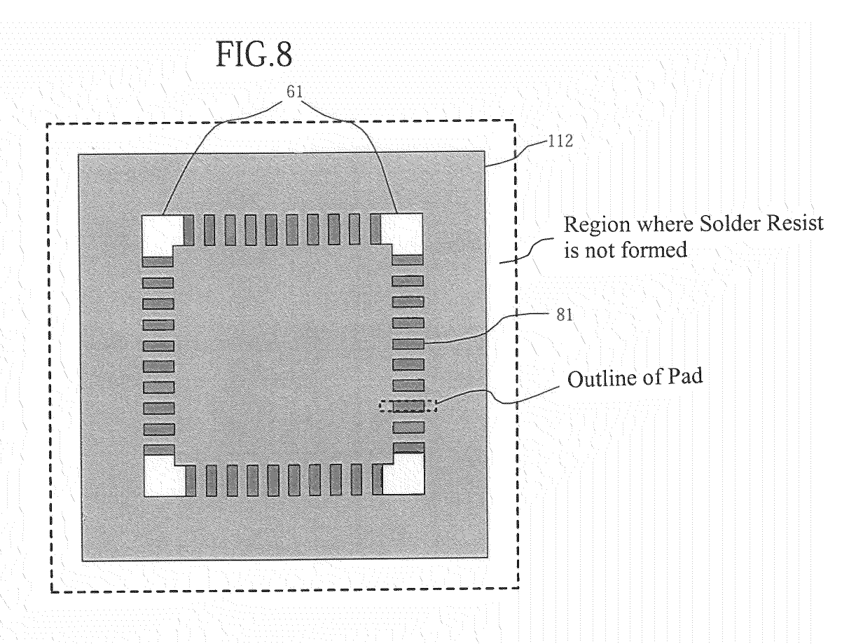

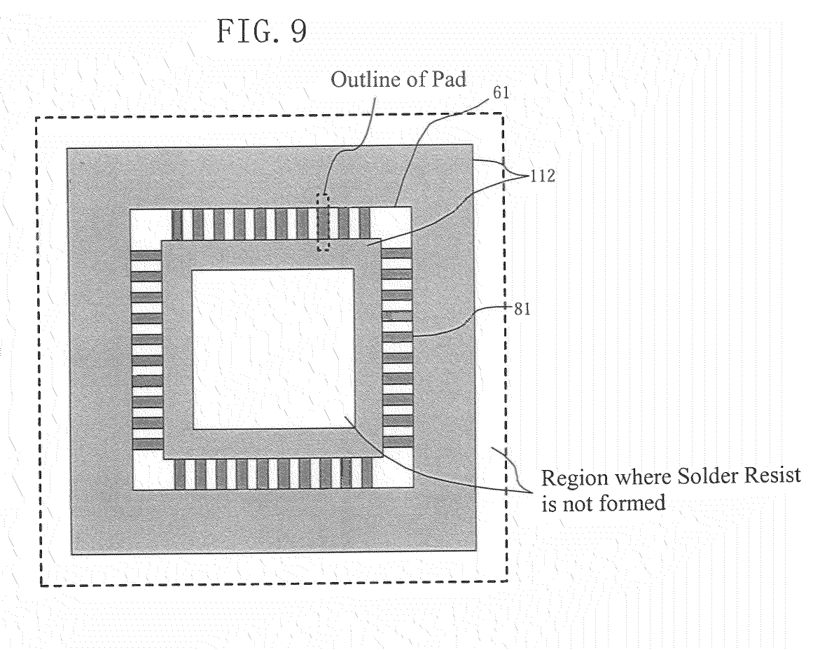

In such a case, as shown in FIG. 8, portions between pads (81) may be covered with solder resist layer (112). Alternatively, as shown in FIG. 9, a region without the solder resist layer may be formed in the center of the region corresponding to the circuit-formed surface of electronic component (2).

Also, to enhance the adhesiveness between the solder resist layer and conductive-pattern layer, the surface of the conductive-pattern layer may be roughened by surface roughening treatments, such as black oxide, chemical etching (CZ treatment) or the like, before the solder resist layer is formed.

Also, in multilayer wiring board (600), a layer formed respectively with either insulation layer (601) or (602) and with either conductive pattern (605) or (606) is laminated on both main surfaces of substrate (1) with a built-in electronic component. However, the present invention is not limited to such. Namely, two or more such layers may be laminated, or the number of laminated layers may be different on each main surface. Furthermore, such layers may be laminated only on either main surface.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board with a built-in electronic component in which an electronic component is flip-chip mounted to be built in, comprising:
a conductive-pattern layer;
a connection terminal formed in the conductive-pattern layer and electrically connected to the electronic component; and
a solder resist layer formed on the conductive-pattern layer, wherein
the solder resist layer is formed around the connection terminal on the conductive-pattern layer, but it is not formed in at least part of the other region on the conductive-pattern layer.

2. The wiring board with a built-in electronic component according to claim 1, wherein the connection terminal includes a connection layer formed on the conductive-pattern layer using a metal other than that of the conductive-pattern layer.

3. The wiring board with a built-in electronic component according to claim 2, wherein the connection layer is made of solder.

4. The wiring board with a built-in electronic component according to claim 1, wherein the solder resist layer covers at least part of the region of the conductive-pattern layer where the connection terminal is formed.

5. The wiring board with a built-in electronic component according to claim 1, wherein the electronic component is covered with an insulative material, and a through-hole conductor is formed in the insulative material.

6. The wiring board with a built-in electronic component according to claim 5, wherein the conductive-pattern layer does not protrude from the surface of the insulative material.

7. The wiring board with a built-in electronic component according to claim 1, wherein a bump for bonding with the connection terminal is formed in the electronic component.

8. The wiring board with a built-in electronic component according to claim 1, wherein the surface of the conductive-pattern layer is roughened.

9. The wiring board with a built-in electronic component according to claim 7, wherein the bump of the electronic component is arranged in the peripheral portion of the surface where the circuit is formed.

10. A method for manufacturing a wiring board with a built-in electronic component, comprising:
forming a conductive-pattern layer on a metal foil of a laminated base material where the metal foil is arranged on a support body;
forming a solder resist layer having a predetermined opening portion in part of the region on the conductive-pattern layer;
forming a connection terminal by forming a connection layer at the spot on the conductive-pattern layer which corresponds to the opening portion of the solder resist layer;
arranging the electronic component on the laminated base material in such a way that the circuit-formed surface of the electronic component faces the surface where the connection terminal is formed, and to electrically connect the electronic component and the connection terminal;
coating the electronic component with an insulative material after the electronic component is mounted;
removing the support body; and
removing the exposed metal foil.

11. The method for manufacturing a wiring board with a built-in electronic component according to claim 10, wherein the connection layer is formed with a metal other than that of the conductive-pattern layer.

12. The method for manufacturing a wiring board with a built-in electronic component according to claim 11, wherein the connection layer is made of solder.

13. The method for manufacturing a wiring board with a built-in electronic component according to claim 10, further comprising forming a through-hole conductor after the electronic component is covered by the insulative material and a through-hole is formed in the insulative material.

14. The method for manufacturing a wiring board with a built-in electronic component according to claim 10, wherein the conductive-pattern layer is formed by electrolytic plating.

15. The method for manufacturing a wiring board with a built-in electronic component according to claim 10, wherein a bump for bonding with the connection terminal is formed in the electronic component.

16. The method for manufacturing a wiring board with a built-in electronic component according to claim 10, further comprising roughening the surface of the conductive-pattern layer after the conductive-pattern layer is formed, but before the solder resist layer is formed.

17. The method for manufacturing a wiring board with a built-in electronic component according to claim 10, further comprising filling insulative resin around the connection terminal after the electronic component is mounted.

18. The method for manufacturing a wiring board with a built-in electronic component according to claim 15, wherein the bump of the electronic component is arranged in the peripheral portion of the surface where the circuit is formed.
